(19) United States
(12) Patent Application Publication
(10) Pub. No.: US 2009/0184330 A1
(43) Pub. Date: Jul. 23, 2009

(54) LIGHT-EMITTING MODULE INCLUDING SUBSTRATE WITH SPACE FORMED AROUND RIM

(75) Inventor: Katsuyuki Okimura, Tokyo (JP)

Correspondence Address: YOUNG & THOMPSON, 209 Madison Street, Suite 500, ALEXANDRIA, VA, 22314, US

(73) Assignee: NEC LIGHTING, LTD, Tokyo (JP)

(21) Appl. No.: 12/349,858

(22) Filed: Jan. 7, 2009

(30) Foreign Application Priority Data
Jan. 22, 2008 (JP) 2008-011390

(51) Int. Cl. H01L 33/00

(52) U.S. Cl. 257/79; 257/E33.075

(57) ABSTRACT

A light-emitting module includes a light-emitting element, a substrate on which are mounted the light-emitting element and heat dissipater. The substrate and heat dissipater are connected together by one mounting member and a space is formed around the rim of the substrate.

This application is based upon and claims the benefit of priority from Japanese patent application No. 2008-011390, filed on Jan. 22, 2008, the disclosure of which is incorporated herein in its entirety by reference

### BACKGROUND OF THE INVENTION

1. Field of the Invention

The present invention relates to a light-emitting module provided with heat dissipater.

2. Description of the Related Art

In recent years, various products for illumination used for a liquid crystal display device, information display board or the like are being commercialized or under study. For example, Japanese Patent Laid-Open No. 06-161359 describes a display using a light-emitting diode (LED). The display described in Japanese Patent Laid-Open No. 06-161359 includes a light-emitter which is a plurality of LEDs integrated into a module.

Furthermore, Japanese Patent Laid-Open No. 2006-344694 describes a light-emitting module including a light-emitting element such as an LED. The light-emitting module described in Japanese Patent Laid-Open No. 2006-344694 includes a porcelain-clad substrate on which a light-emitting element is mounted. The porcelain-clad substrate is a substrate made of core metal covered with a porcelain-clad layer. The porcelain-clad substrate has good heat dissipation characteristics and many LEDs can be mounted on it. Furthermore, the above described document also describes that warpage of the porcelain-clad substrate produced when the core metal is clad with the porcelain-clad layer is reduced by forming a folded part at least at one side of this porcelain-clad substrate. Mounting holes are formed in the four corners of the porcelain-clad substrate and the porcelain-clad substrate is fixed to the lighting apparatus body with screws fitted in the mounting holes.

Light-emitting elements such as LED generate heat during light emission. In particular, the modules including a plurality of LEDs described in Japanese Patent Laid-Open No. 06-161359 and Japanese Patent Laid-Open No. 2006-344694 have a greater heating value as the number of LEDs increases. When the substrate is heated to a high temperature by the heat produced, there is a problem that the substrate is deformed. Therefore, it is desirable to efficiently dissipate heat produced during light emission by using a lighting apparatus body that has high heat dissipation characteristics or that has heat dissipater such as heat sink,

FIG. 1 is a front view of a light-emitting module including a heat sink, which is a heat dissipater. Furthermore, FIG. 2A is a cross-sectional view of the light-emitting module along line C-C in FIG. 1. The light-emitting module includes substrate 30 where light-emitters 39 are arranged in a lattice form. Light-emitter 39 is provided with light-emitting element 32. Furthermore, substrate 30 is provided with power supply 33. Furthermore, a circuit (not shown) is formed in substrate 30 and this circuit electrically connects power supply 33 and light-emitting elements 32.

Furthermore, as in the case of the substrate described in Japanese Patent Laid-Open No. 2006-344694, mounting holes 31 are formed in the four corners of substrate 30 shown in FIG. 1. A recessed part is formed in heat sink 34 and recessed part bottom surface 34a is configured to be flat. Substrate 30 is mounted on recessed part bottom surface 34a of heat sink 34. Screws 35 are fitted in four mounting holes 31. Substrate 30 and heat sink 34 are connected together by these screws 35. Heat sink 34 dissipates heat produced from light-emitting elements 32 provided on substrate 30.

For explanation, screws 35 are not fitted in mounting holes 31 shown in FIG. 1.

Here, as long as substrate 30 and heat sink 34 are made of different materials, both materials have different coefficients of linear thermal expansion. Therefore, substrate 30 is subject to stress resulting from an external force from heat sink 34 caused by thermal expansion or thermal contraction. When the coefficient of linear thermal expansion of substrate 30 is greater than that of heat sink 34, the central part of substrate 30 warps as shown in FIG. 2B as temperature rises. A gap is then produced between substrate 30 and heat sink 34, and air space 37 is formed. This air space 37 deteriorates the efficiency of thermal conduction from substrate 30 to heat sink 34. On the other hand, when the coefficient of linear thermal expansion of heat sink 34 is greater than that of substrate 30, substrate 30 is pulled in four directions as the temperature rises. In this case, cracks may be produced in the joint between light-emitter 39 and substrate 30, and the circuit formed in substrate 30.

FIG. 3A is a cross-sectional view of another light-emitting module provided with a heat sink. The light-emitting module shown in FIG. 3A has substantially the same configuration as that of the light-emitting module shown in FIG. 2A. A mounting hole is formed in the center of substrate 50 of this light-emitting module. Substrate 50 and heat sink 54 are connected together by screw 55 fitted in the mounting hole. Furthermore, the light-emitting module has outer shell 58 that contacts the rim of substrate 50 (the part forming the side wall of the recessed part of heat sink 54). Since outer shell 58 hinders thermal expansion of substrate 50, warpage occurs in substrate 50 as heat is generated (see FIG. 3B). When warpage occurs in substrate 50 due to heat during light emission, air space 57 is formed between substrate 50 and heat sink 54. Such air space 57 causes deterioration of heat dissipation efficiency.

### SUMMARY

It is an object of the present invention to solve the above described problems. An exemplary object of the invention is to provide a light-emitting module that reduces warpage of the substrate due to heat generation during light emission and that mitigates deterioration of heat dissipation efficiency.

A light-emitting module according to an exemplary aspect of the invention includes a light-emitting element, a substrate, and heat dissipater. The light-emitting element is mounted on the substrate. The substrate and heat dissipater are connected together by one mounting member and a space is formed around the rim of the substrate.

The configuration of the present invention reduces warpage of the substrate and mitigates deterioration of heat dissipation efficiency of the light-emitting module.

The above and other objects, features and advantages of the present invention will become apparent from the following description with reference to the accompanying drawings which illustrate examples of the present invention.

### BRIEF DESCRIPTION OF THE DRAWINGS

FIG. 1 is a front view of a light-emitting module according to a related art;

FIG. 2A is a cross-sectional view of the light-emitting module along line C-C in FIG. 1;

FIG. 2B is a schematic diagram showing a situation in which thermal expansion takes place in the substrate shown in FIG. 2A;

FIG. 3A is a cross-sectional view of a light-emitting module according to another related art;

FIG. 3B is a schematic diagram showing a situation in which thermal expansion takes place in the substrate shown in FIG. 3A;

FIG. 4 is a front view of a light-emitting module according to an exemplary embodiment;

FIG. 5 is a cross-sectional view of the light-emitting module along line A-A in FIG. 4;

FIG. 6 is a front view of the light-emitting module according to the exemplary embodiment; and

FIG. 7 is a cross-sectional view of the light-emitting module along line B-B in FIG. 6.

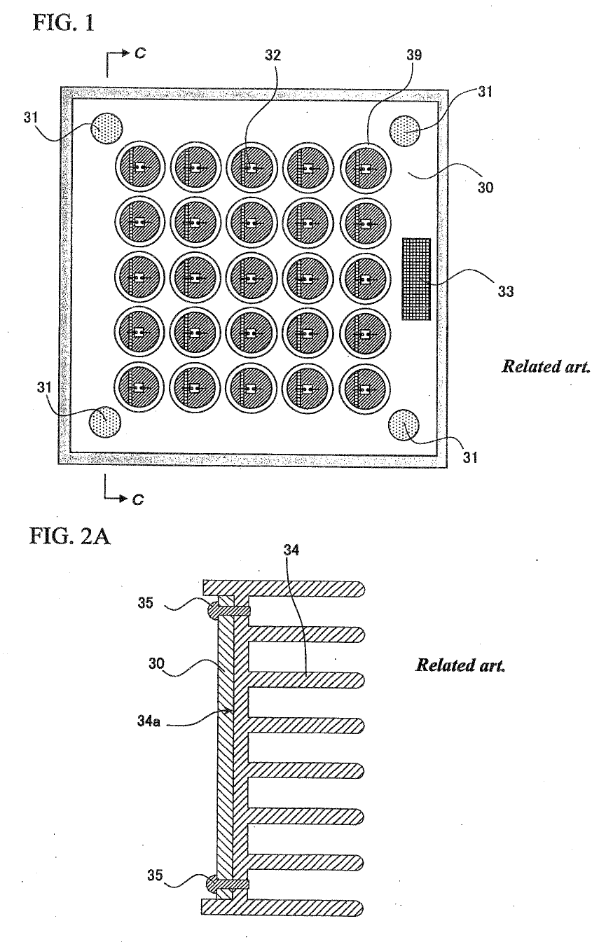

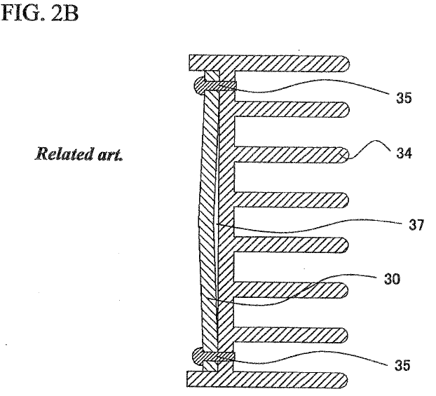

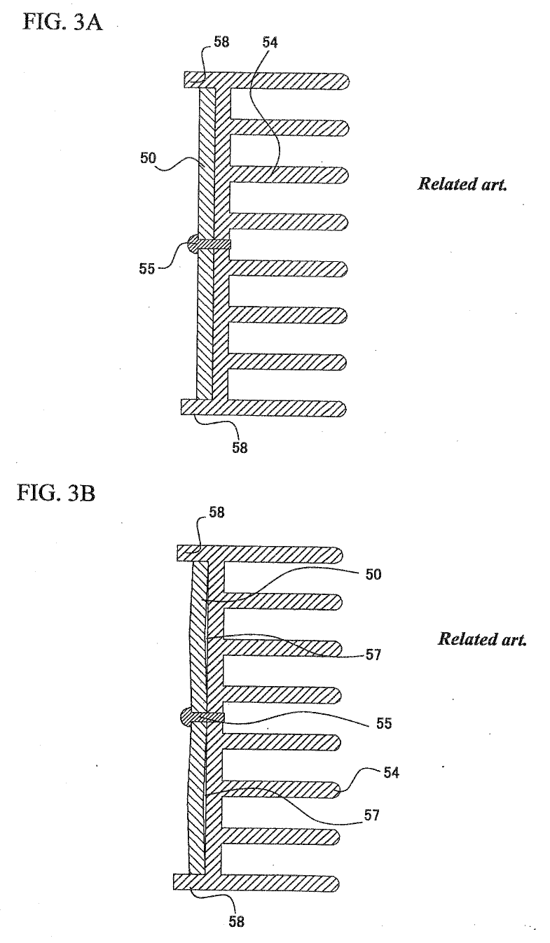

### DETAILED DESCRIPTION OF THE EXEMPLARY EMBODIMENTS

Hereinafter, exemplary embodiments will be explained with reference to the attached drawings.

### First Exemplary Embodiment

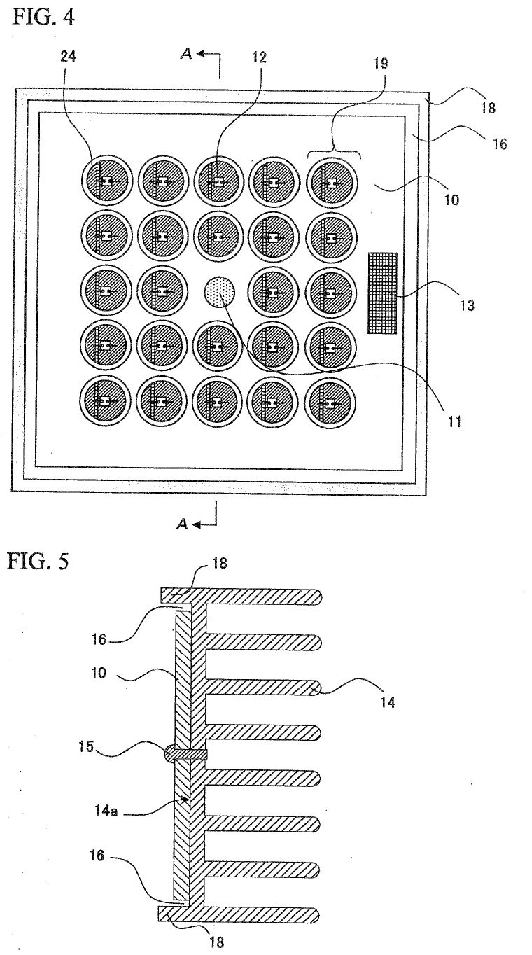

FIG. 4 is a front view of a light-emitting module according to an exemplary embodiment and FIG. 5 is a schematic cross-sectional view of the light-emitting module along line A-A in FIG. 4. However, light-emitters 19 are omitted in FIG. 5. The light-emitting module includes substrate 10, a plurality of light-emitters 19 mounted on substrate 10 in a lattice form and heat sink 14, which is a heat dissipater. Light-emitter 19 includes light-emitting element 12, for example a light-emitting diode (LED).

Substrate 10 is made up of a multi-layer board and includes an insulator in which conductive wiring 24 is formed. Wiring 24 forms a circuit and the surface of wiring 24 is covered with an insulating layer. Substrate 10 of light-emitter 19 is shaped like a mortar by a cutting process. Wiring layer 24 is exposed from the bottom surface of this mortar shape. Light-emitting element 12 is mounted on the bottom surface of the mortar shape. Light-emitting element 12 is connected to wiring layer 24 through a conductive wire such as a metal wire. Furthermore, light-emitter 19 may also be covered with transparent resin to improve the reliability of the light-emitting module.

Substrate 10 is provided with power supply 13. Wiring 24 electrically connects light-emitting elements 12 and power supply 13. Light-emitting elements 12 emit light when power supply 13 supplies power to light-emitting elements 12. The configuration of light-emitter 19 is not limited to the above described configuration and various known configurations can be used. Furthermore, light-emitting elements 12 are not limited to light-emitting diodes.

One mounting hole 11 is formed in substrate 10. A recessed part is formed in heat sink 14 and bottom surface 14a of the recessed part is configured to be flat. Substrate 10 is placed on bottom surface 14a of the recessed part. While keeping mounting hole 11 of substrate 10 aligned with the mounting hole formed in heat sink 14, screw 15, which is a mounting member, is fitted into both mounting holes. This causes substrate 10 and heat sink 14 to be connected together in close contact with each other. Mounting hole 11 may be formed at any location of substrate 10, but may be preferably formed in the vicinity of the center of substrate 10 to increase the close contact between substrate 10 and heat sink 14.

Screw 15, a boss, a projection and so on may be used as a amounting member.

A gap (space 16) is formed around the rim 10a of substrate 10. Outer shell 18 is formed around space 16. Outer shell 18 is the part forming the side wall of the recessed part of heat sink 14. According to this configuration, the rim 10a of substrate 10 does not contact outer shell 18 and space 16 is formed around the rim 10a of substrate 10. This allows substrate 10 to expand freely. Space 16 is required to have a degree of breadth that does not hinder thermal expansion of substrate 10 during light emission.

According to the present exemplary embodiment, one screw 15 is provided for substrate 10. Therefore, substrate 10 expands outward centered on the location where screw 15 is provided. That is, even when the coefficient of linear thermal expansion of substrate 10 is different from that of heat sink 14, the thermal expansion of substrate 10 is not hindered. Therefore, warpage of substrate 10 in the event of thermal expansion is drastically reduced and the condition in which substrate 10 is in close contact with heat sink 14 is kept. This can prevent the heat dissipation efficiency of the light-emitting module from deteriorating and prevent deterioration of reliability.

### Second Exemplary Embodiment

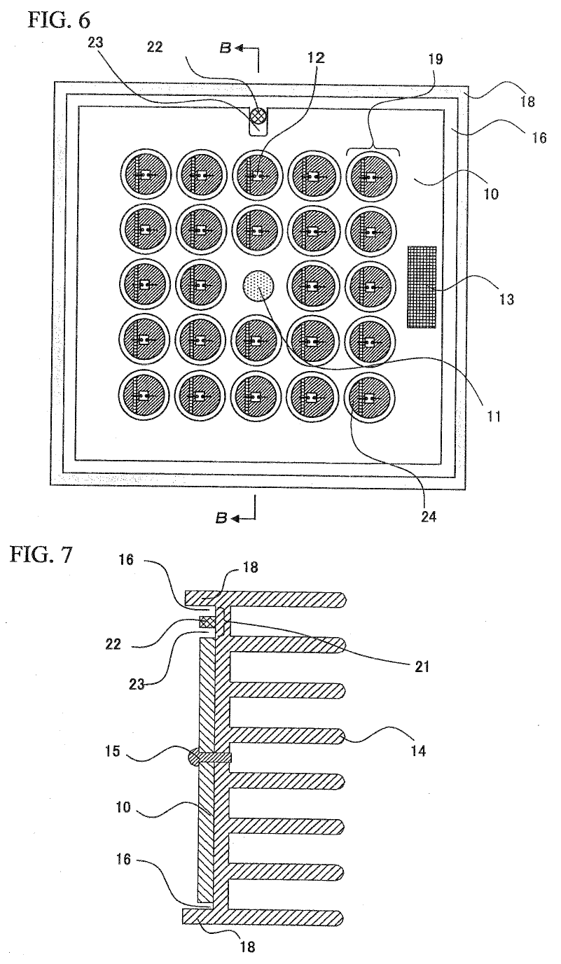

FIG. 6 is a front view of a light-emitting module according to a second exemplary embodiment. Furthermore, FIG. 7 is a cross-sectional view of the light-emitting module along line B-B in FIG. 6. However, light-emitters 19 are omitted in FIG. 7.

The light-emitting module according to the present exemplary embodiment has substantially the same configuration as that of the light-emitting module of the first exemplary embodiment and includes substrate 10, a plurality of light-emitters 19 mounted on substrate 10 in a lattice form and heat sink 14, which is heat dissipater. Light-emitter 19 includes light-emitting element 12, for example a light-emitting diode. Substrate 10 is provided with power supply 13. Furthermore, a circuit made up of wiring 24 is formed in substrate 10. The circuit electrically connects light-emitting elements 12 and power supply 13.

One mounting hole 11 is formed in the center of substrate 10. Screw 15, which is a mounting member, is fitted into this mounting hole 11 and a mounting hole formed in heat sink 14. This causes substrate 10 to be connected to heat sink 14 in close contact with each other. Furthermore, a gap (space 16) is formed in the rim 10a of substrate 10. Part of heat sink 14 is located around space 16 as outer shell 18. As shown in the figure, the rim 10a of substrate 10 does not contact outer shell 18 and space 16 is formed around the rim 10a of substrate 10.

Notch 21 is formed in a portion of the rim 10a of substrate 10 of the light-emitting module according to the present exemplary embodiment. Boss 22 fixed to heat sink 14 is provided in notch 21. Furthermore, space 23 is formed between the rim 10a of substrate 10 and boss 22 on a straight line connecting boss 22 and screw 15 attached to substrate 10. Provision of boss 22 can prevent substrate 10 from rotating in the rotation direction of screw 15 when screw 15 is fitted into mounting hole 11.

When the temperature of substrate 10 rises, substrate 10 expands in a radial direction centered on screw 15. Since space 23 is formed between boss 22 and substrate 10, the thermal expansion of substrate 10 is not hindered. In this way, even when boss 22 for preventing rotation of substrate 10 is provided, warpage of substrate 10 is reduced and deterioration of heat dissipation efficiency is mitigated.

Whenever necessary, boss 22 may be removed after screw 15 is attached to substrate 10. This prevents substrate 10 from contacting boss 22. Therefore, warpage of substrate 10 caused by thermal expansion is further mitigated.

According to the present exemplary embodiment, one boss 22 for preventing rotation of substrate 10 is provided, but any number of bosses may be provided if warpage of the substrate does not increase. Furthermore, boss 22 may be located at any place if it is at least around the rim 10a of substrate 10.

The present invention is not limited to the above described exemplary embodiments. For example, the number of light-emitters 19 and their locations are not limited to the above described exemplary embodiments. In the above described exemplary embodiments, outer shell 18 is part of heat sink 14, but outer shell 18 may also be any member of the lighting apparatus body. The shape of heat sink 14 is not limited to the shape of the above described exemplary embodiments. The light-emitting module of the present invention is required only to include space 16 around the rim 10a of substrate 10. Furthermore, the above described exemplary embodiments use heat sink 14 as the heat dissipater, but the heat dissipater may also be the body of the lighting apparatus mounted with the light-emitting module.

Furthermore, the configuration of the substrate and light-emitters is not limited to the configuration of the above described exemplary embodiments, but various known configurations can be used. The “substrate” in the present specification may also be mold resin. In this case, the light-emitting module is manufactured using molding process. That is, light-emitters and a circuit or the like are mounted on the mold resin. The mold resin is then connected to heat dissipater by one screw and a space is formed in the rim of the mold resin.

While preferred embodiments of the present invention have been described using specific terms, such description is for illustrative purposes only, and it is to be understood that changes and variations may be made without departing from the spirit or scope of the following claims.

What is claimed is:

1. A light-emitting module comprising:
a light-emitting element;
a substrate on which the light-emitting element is mounted; and
heat dissipater,
wherein the substrate and the heat dissipater are connected together by one mounting member and a space is formed around a rim of the substrate.

2. The light-emitting module according to claim 1, wherein the mounting member is attached in the vicinity of the center of the substrate.

3. The light-emitting module according to claim 1, wherein the light-emitting element is a light-emitting diode.

4. The light-emitting module according to claim 1, wherein at least one boss is fixed to the heat dissipater,
a notch is formed in the rim of the substrate, and
the boss is disposed in the notch.

5. The light-emitting module according to claim 4, wherein a space is formed between the substrate and the boss on a straight line connecting the mounting member and the boss.

6. The light-emitting module according to claim 1, wherein the heat dissipater comprise a recessed part,
the substrate is attached to a bottom surface of the recessed part, and
the substrate is provided so that the space is formed between the rim of the substrate and an outer shell which is a side wall of the recessed part.
